(19) United States
(12) Patent Application Publication
(10) Pub. No.: US 2008/0124849 A1
(43) Pub. Date: May 29, 2008

(54) FABRICATING METHOD OF SEMICONDUCTOR DEVICE

(76) Inventor: Kyung-Min Park, Incheon (KR)

Correspondence Address: SHERR & NOURSE, PLLC, 620 HERNDON PARKWAY, SUITE 200, HERNDON, VA, 20170, US

(21) Appl. No.: 11/869,518

(22) Filed: Oct. 9, 2007

(30) Foreign Application Priority Data
Nov. 29, 2006 (KR) 10-2006-0118695

(51) Int. Cl. H01L 21/84; H01L 21/00

(52) U.S. Cl. 438/166

(57) ABSTRACT

The embodiment relates to a fabricating method of a semiconductor device, the method comprising the steps of: forming a gate oxide film, a gate electrode, and a side spacer on a semiconductor substrate; forming a source/drain area by implanting ion on the semiconductor substrate; forming a carbon layer on the nickel silicide surface by performing a primary thermal processing process on the nickel silicide film; and removing the carbon layer by performing a secondary thermal processing process on the nickel silicide film under an ambient gas.

The present application claims priority under 35 U.S.C. 119 and 35 U.S.C. 365 to Korean Patent Application No. 10-2006-0118695 (filed on Nov. 29, 2006), which is hereby incorporated by reference in its entirety.

### BACKGROUND

Aspects of semiconductor technology have focused on high speed semiconductor devices that are highly integrated. High integration can be accomplished by miniaturizing various patterns constituting the semiconductor device. Miniaturizing the patterns, however, may increase the resistance of the semiconductor device, and thus, may result in a semiconductor device having a slow operating speed with increased power consumption.

Fabricating of semiconductor devices have used instead of polysilicon metal silicides such as tungsten silicide, titanium silicide, or cobalt silicide, and the like.

### SUMMARY

Embodiments relate to a method of fabricating a semiconductor device that reduces the resistance of the semiconductor device by depositing a nickel silicide film using an ALD method.

Embodiments relate to a method of fabricating a semiconductor method including at least one of the following steps: forming a gate oxide film, a gate electrode, and a side spacer on a semiconductor substrate; forming a source/drain area by implanting ion on the semiconductor substrate; forming nickel silicide film on the semiconductor substrate formed with the gate electrode and the source/drain area; forming a carbon layer on the nickel silicide surface by performing a primary thermal processing process on the nickel silicide film; and removing the carbon layer by performing a secondary thermal processing process on the nickel silicide film under gas ambient.

### DRAWINGS

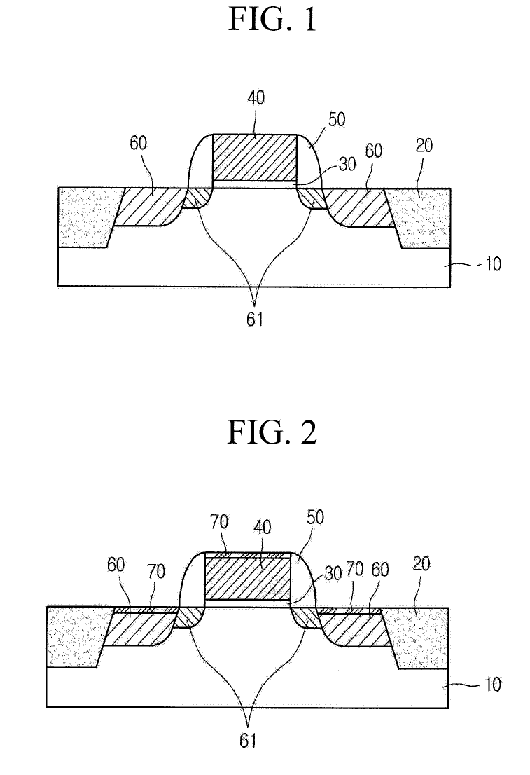

Example FIGS. 1 to 5 illustrate a fabricating method of a semiconductor device, in accordance with embodiments.

### DESCRIPTION

As illustrated in example FIG. 1, semiconductor substrate 10 can be formed with device isolating layer 20 defining an active area and a field area. The device isolating layer 20 can be formed using shallow trench isolation (STI).

Semiconductor substrate 10 can be formed of a single crystalline silicon substrate. For example, semiconductor substrate 10 may be a substrate doped with a P-type impurity or an N-type impurity.

A transistor is formed on and/or over semiconductor substrate 10. The transistor forming process stacks an oxide film and a polysilicon film on and/or over semiconductor substrate 10 and sequentially forms gate oxide film 30 and gate electrode 40 using an etching process. Gate electrode 40 may be a single layer or a multilayer film. Gate electrode 40 may be composed of at least one of a polysilicon and a metal. When gate electrode 40 is formed of polysilicon, the polysilicon can be formed into a metal gate for the operation of a highly integrated semiconductor device.

Semiconductor substrate 10 can be formed with a lightly doped drain (LDD) region 61 using a low-concentration dopant ion implant (N-type or P-type impurity) using gate electrode 40 as a mask.

An insulating layer can then be deposited on and/or over semiconductor substrate 10 and side spacer 50 contacting both side walls of gate electrode 40 can be formed using a blanket etch process.

Source/drain region 60 electrically connected to LDD region 61 can be formed using a high-concentration dopant ion implant using gate electrode 40 and spacer 50 as masks. Source/drain region 60 can be formed of N-type or P-type dopant ions. A thermal processing process can be performed to activate the dopant implanted into source/drain area 60.

As illustrated in example FIG. 2, a nickel layer can be deposited on and/or over gate electrode 40 and source/drain area 60 and a rapid thermal process (RTP) can be performed thereon. The nickel layer forms a NiSi compound using the contact with the silicon portion of the lower thereof so that nickel silicide film 70 is formed. Nickel silicide film 70 serves to lower contact resistance between the semiconductor device and a wiring.

Nickel silicide film 70 can be deposited using an atomic layer deposition (ALD) method. Gate electrode 40 and source/drain area 60 of semiconductor substrate 10 can be formed with nickel silicide film 70 having a minute thickness and a uniform thickness in an atomic layer unit.

The atomic layer deposition method is a method forming a thin film having a minute thickness in an atomic layer unit. The atomic layer deposition method is a method that does not supply raw material gases for forming a thin film at the same time but supplies in an independent pulse form by time-dividing them. When supplying the raw material gases, valves installed in each gas pipe are opened and closed having the time difference so that the respective gases are supplied to a reactor having the time difference without being mixed. When the gases are supplied in a time division at a preset flux, purge gas is supplied in the middle of supplying the gases so that the gases remained due to non-reaction suffers from a removing process in the reactor. Such an atomic layer deposition method has the advantages that it can form a thin film having excellent step coverage and a uniform thickness over a large area substrate and finely control the thickness of the thin film by controlling the repeating times.

Accordingly, the nickel depositing method using an atomic layer deposition method uses a precursor in an Ni-CxHy(x,y is 0 or a natural number) form as the raw material to form nickel silicide film 70 on and/or over semiconductor substrate 10 using a pyrosis at a temperature of about 350 to 400° C.

Nickel silicide film 70 may include a considerable amount of carbon impurities. Thus, the undesirable carbon impurities should be removed since they serve to increase resistance in the silicide film.

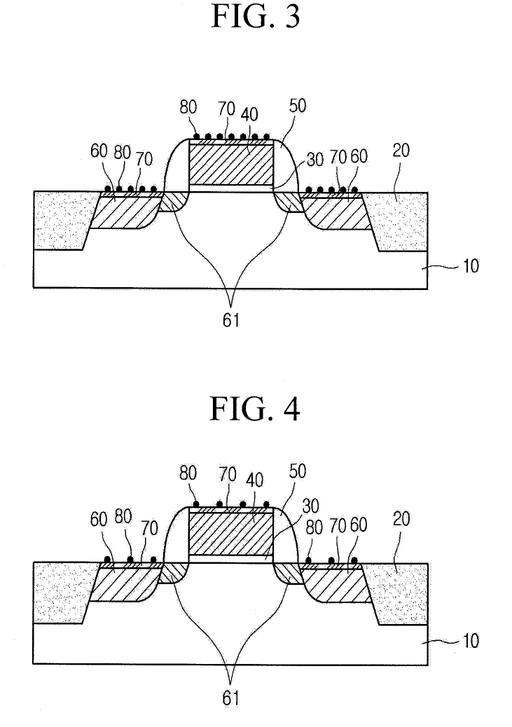

As illustrated in example FIG. 3, in order to remove the carbon impurities, a primary thermal processing process can be performed on and/or over semiconductor substrate 10 formed with nickel silicide film 70. The primary thermal processing process can be performed at a temperature of about approximately 500 to 600° C. The carbon distributed in nickel silicide film 70 can be diffused to the uppermost surface of nickel silicide film 70. Accordingly, carbon layer 80 can be formed on and/or over the uppermost surface of nickel silicide film 70. Carbon layer 80 may be in a single layer or a multilayer.

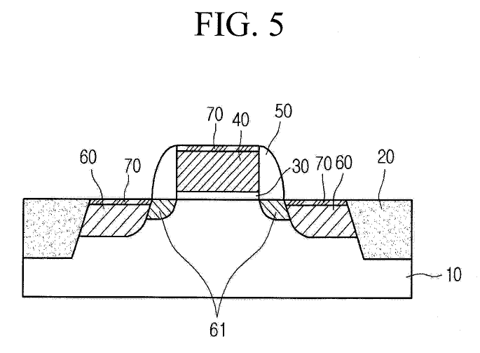

As illustrated in example FIGS. 4 and 5, a secondary thermal processing process can be performed on and/or over semiconductor substrate 10 formed with carbon layer 80. The secondary thermal processing process can be performed at a high temperature of about 500 to 600° C. under gas ambient using O₂ gas. The O₂ gas reacts with the carbon atoms in carbon layer 80 to form CO₂ to thereby remove carbon layer 80. Accordingly, nickel silicide film 70 remains.

In accordance with embodiments, in order to remove carbon layer 80 formed on and/or over the uppermost surface of nickel silicide film 70, a secondary thermal processing process can be performed at a high temperature of 500 to 600° C. under gas ambient using O₃ gas. The O₃ gas reacts with the carbon atoms in carbon layer 80 to form CO₃ to thereby remove carbon layer 80. Accordingly, nickel silicide film 70 remains.

The fabricating method of the semiconductor device in accordance with embodiments has an effect that nickel silicide film 70 can be formed on and/or over semiconductor substrate 10 using an ALD method to have a uniform and minute thickness, making it possible to improve the quality of the semiconductor device.

Furthermore, the fabricating method of the semiconductor device in accordance with embodiments has an effect that the thermal processing process can be performed on and/or over nickel silicide film 70 to remove carbon impurities so that the resistance in the ohmic contact with the metal layer can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a gate oxide film, a gate electrode, and a side spacer on a semiconductor substrate;
forming a source/drain area by implanting ion on the semiconductor substrate;
forming nickel silicide film on the semiconductor substrate formed with the gate electrode and the source/drain area
forming a carbon layer on the nickel silicide surface by performing a primary thermal processing process on the nickel silicide film; and
removing the carbon layer by performing a secondary thermal processing process on the nickel silicide film under gas ambient.

2. The method of claim 1, wherein the nickel silicide film uses a precursor in a Ni-CxHy form using an atomic layer deposition method.

3. The method of claim 2, wherein the nickel silicide film is formed at a temperature of 350 to 400° C. using the atomic layer deposition method.

4. The method of claim 1, wherein the primary thermal processing process on the nickel silicide film is performed at a temperature of between approximately 500 to 600° C.

5. The method of claim 1, wherein the secondary thermal processing process on the nickel silicide film is performed at a temperature of between approximately 500 to 600° C.

6. The method of claim 1, wherein the secondary thermal processing process on the nickel silicide film is performed in O₂ gas ambient.

7. The method of claim 1, wherein the secondary thermal processing process on the nickel silicide film is performed in O₃ gas ambient.

8. A method comprising:
forming a pair of device isolation areas defining active areas and field areas in a semiconductor substrate;
forming a gate oxide film over the semiconductor substrate;
forming a gate electrode over the semiconductor substrate including the gate oxide film;
forming a pair of lightly doped drain regions in the semiconductor substrate;
forming a pair of spacers contacting both side walls of the gate electrode;
forming a pair of source/drain region electrically connected to the lightly doped drain region using a high-concentration dopant ion implant and the gate electrode and the pair of spacers as masks;
forming a nickel silicide film over the semiconductor substrate including the gate electrode and the source/drain regions;
removing carbon impurities from the nickel silicide film to form a carbon layer over the semiconductor substrate including the gate electrode and the source/drain regions; and then
removing the carbon layer from the semiconductor substrate including the gate electrode and the source/drain regions.

9. The method of claim 8, wherein the device isolating layers are formed using shallow trench isolation, the gate oxide film and the gate electrode are sequentially formed using an etching process, the pair of spacers are formed using a blanket etch process, and the nickel silicide film is deposited using an atomic layer deposition method.

10. The method of claim 8, wherein the semiconductor substrate comprises a single crystalline silicon substrate.

11. The method of claim 10, wherein the single crystalline silicon substrate is doped with at least one of a P-type impurity and an N-type impurity.

12. The method of claim 8, wherein the lightly-doped drain regions are formed using a low-concentration dopant ion implant and the gate electrode as a mask

13. The method of claim 8, wherein the pair of source/drain regions are formed of at least one of N-type and P-type dopant ions.

14. The method of claim 13, wherein the at least one of N-type and P-type dopant ions are activated using a thermal processing process.

15. The method of claim 8, wherein the nickel silicide film is formed by depositing a nickel layer over the semiconductor substrate including the gate electrode and the source/drain regions conducting a rapid thermal process thereon.

16. The method of claim 8, wherein the carbon impurities are removed using a primary thermal processing process on the semiconductor substrate at a temperature of about approximately 500 to 600° C.

17. The method of claim 8, wherein the carbon layer is removed using a secondary thermal processing process on the semiconductor substrate at a temperature of about approximately 500 to 600° C. using ambient O₂ gas.

18. The method of claim 8, wherein the carbon layer is removed using a secondary thermal processing process on the semiconductor substrate at a temperature of about approximately 500 to 600° C. using ambient O₃ gas.

19. An apparatus comprising:
a device isolation area defining an active area and a field area in a semiconductor substrate;
a gate oxide film formed over the semiconductor substrate;
a gate electrode over the semiconductor substrate including the gate oxide film;
a pair of lightly doped drain regions formed in the semiconductor substrate;
a pair of spacers contacting both side walls of the gate electrode;
a pair of source/drain region electrically connected to the lightly doped drain region using a high-concentration dopant ion implant and the gate electrode and the pair of spacers as masks;
a nickel silicide film formed over the semiconductor substrate including the gate electrode and the source/drain regions.

20. The apparatus of claim 19, wherein carbon impurities are removed from the nickel silicide film using a primary thermal processing process on the semiconductor substrate at a temperature of about approximately 500 to 600° C.
